(19) United States
(12) Patent Application Publication
(10) Pub. No.: US 2022/0074627 A1
(43) Pub. Date: Mar. 10, 2022

(54) COOLING SYSTEM FOR PROCESSING CHAMBER

(71) Applicant: LAM RESEARCH CORPORATION, Fremont, CA (US)

(72) Inventors: Kevin FLYNN, Novato, CA (US); Travis BENTZ, Fremont, CA (US); Alexander Charles MARCACCI, San Jose, CA (US); Christophe VIVENSANG, Saratoga, CA (US)

(21) Appl. No.: 17/423,228

(22) PCT Filed: Jan. 29, 2020
(86) PCT No.: PCT/US2020/015564

§ 371 Date: Jul. 15, 2021

Related U.S. Application Data
(60) Provisional application No. 62/799,597, filed on Jan. 31, 2019.

(51) Int. Cl. F25B 9/10; F25B 9/00; F25B 29/00; H01J 37/32

(52) U.S. Cl. CPC F25B 9/10; F25B 9/008; F25B 9/145; H01J 37/32724; F25B 29/00

(57) ABSTRACT

An apparatus is provided. The apparatus comprises a processing chamber. A substrate support is within the processing chamber, wherein the substrate support is in thermal contact with a substrate. A cooling system cools the substrate support. The cooling system comprises a first refrigeration system. The first refrigeration system comprises a first refrigerant inlet for receiving the first refrigerant from a first refrigerant source outside of the refrigeration system, wherein the first refrigerant is at a first pressure, a first throttle, wherein the first throttle allows a controlled expansion of the first refrigerant, wherein the expansion of the first refrigerant cools the first refrigerant, a first heat transfer system, for absorbing heat and transferring heat to the cooled first refrigerant, and a first refrigerant return for directing the first refrigerant from the first refrigeration system at a second pressure away from the first refrigeration system.

### CROSS-REFERENCE TO RELATED APPLICATION

This application claims the benefit of priority of U.S. Application No. 62/799,597, filed Jan. 31, 2019, which is incorporated herein by reference for all purposes.

### BACKGROUND

The disclosure relates to a method of forming semiconductor devices on a semiconductor wafer. More specifically, the disclosure relates to systems for plasma or non-plasma processing semiconductor devices.

In forming semiconductor devices, stacks are subjected to processing in a plasma processing chamber. Such processes may require ultralow or cryogenic temperatures.

### SUMMARY

To achieve the foregoing and in accordance with the purpose of the present disclosure, an apparatus is provided. The apparatus comprises a processing chamber.

A substrate support is within the processing chamber, wherein the substrate support is for thermal contact with a substrate. A cooling system cools the substrate support. The cooling system comprises a first refrigeration system. The first refrigeration system comprises a first refrigerant inlet for receiving the first refrigerant from a first refrigerant source outside of the refrigeration system, wherein the first refrigerant is at a first pressure, a first throttle, wherein the first throttle allows a controlled expansion of the first refrigerant, wherein the expansion of the first refrigerant cools the first refrigerant, a first heat transfer system, for absorbing heat and transferring heat to the cooled first refrigerant, and a first refrigerant return for directing the first refrigerant from the first refrigeration system at a second pressure away from the first refrigeration system.

In another manifestation, an apparatus for processing a substrate is provided comprising a processing chamber and the supporting subsystems for the process module. A substrate support is within the processing chamber. A cooling system provides at least 20 kWatts of cooling, wherein the cooling system has a footprint with dimensions less than or equal to the footprint of the processing chamber or the process module.

In another manifestation, an apparatus for processing a substrate comprises a processing chamber and the supporting subsystems for a process module. A substrate support is within the processing chamber, wherein the substrate support comprises various components, layers, and coatings. The process module also includes other adjacent subsystems mounted to or in close proximity to the process chamber needed for the process to occur. This includes but is not limited to power boxes, RF generators, gas boxes, pumps, etc. A cooling system cools the substrate support such that no damage or degradation occurs to the substrate support due to the temperature changes that occur when switching from one temperature set point to another, especially when rapidly switching the coolant source from one channel to another.

In another manifestation, an apparatus for processing a substrate comprises a processing chamber and the supporting subsystems for a process module. A substrate support is within the processing chamber. A cooling system cools the substrate support. The cooling system comprises a first refrigeration system with a first refrigerant comprising carbon dioxide (CO₂). The cooling system comprises a first compressor for compressing the first refrigerant to first pressure, a first heat transfer device for transferring heat from the compressed first refrigerant, a first throttle, wherein the first throttle allows a controlled expansion of the first refrigerant, wherein the expansion of the first refrigerant cools the first refrigerant, and an at least one channel in the substrate support, wherein the first refrigerant flows through the at least one channel.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic view of a cooling system in an embodiment.

FIG. 2 is a schematic view of a temperature control system in an embodiment.

FIG. 3 is a schematic view of a processing tool in an embodiment.

FIG. 4 is a schematic view of another cooling system in another embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

In semiconductor device fabrication, a plasma may be used for etching various layers or depositing layers, such as in plasma enhanced deposition. It has been found that during such plasma processing, a substrate may need to be cooled. Requirements for such cooling may require providing a refrigerant at a temperature of below −75° C. and a liquid coolant temperature of below −70° C. Such cooling systems also require high cooling capacities. Some systems may require providing a refrigerant at a temperature below −135° C. In plasma processing systems, refrigeration systems are typically located in a subfab on a floor above or below the plasma processing system and must fit within the space requirements provided by the plasma processing system such that the footprint of the refrigeration system must fit within the footprint of the plasma processing system also referred to as a process module. The standard SEMI E:72 provides industry standards for the size of a process module. Alternatively, refrigerant temperatures as low as of −80° C., −90° C., −100° C., −110° C., −120° C., −130° C., −150° C., −160° C. and −180° are also expected to be beneficial.

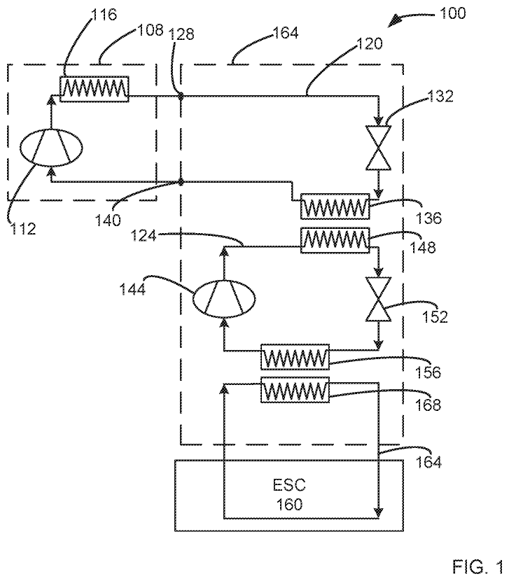

FIG. 1 is a schematic view of an embodiment of a cooling system 100 for a plasma processing tool. The cooling system 100 uses a condensed or supercritical first refrigerant from a fabrication facility 108. The fabrication facility 108 has a facility compressor 112 that compresses the first refrigerant. In this example, the refrigerant is CO₂ The CO₂ is compressed to a pressure above 650 pounds per square inch (psi) (4×10⁶ pascals (Pa)). The compressed CO₂ is cooled in a cooler 116 to a temperature, where the CO₂ condenses. At 650 psi to 1000 psi CO₂ is a liquid at temperatures between 10° C. to 30° C. The cooling system 100 is a cascade cooling system with a high stage 120 and a low stage 124. The high stage 120 is a refrigeration system that comprises an inlet 128, a first throttle 132, a first heat transfer system 136, and a refrigerant return 140. The inlet 128 receives the condensed first refrigerant from the fabrication facility 108. The first throttle 132 provides a controlled expansion of the first refrigerant. For a CO₂ refrigerant, the first throttle provides a pressure of less than 100 psi (7×10⁵ Pa) and above the triple point of CO₂. In alternate embodiments, the first throttle lowers the CO₂ pressure to a pressure greater than one of 100 psi (7×10⁵ Pa), 300 psi (21×10⁵ Pa), 500 psi (35×10⁵ Pa). The controlled expansion of the first refrigerant causes the first refrigerant to cool. The first throttle 132 helps to control the temperature of the expanded first refrigerant. The first heat transfer system 136 absorbs heat. The absorbed heat increases the temperature of the first refrigerant. The first refrigerant is then vented through the refrigerant return 140 back to the fabrication facility 108.

The low stage 124 comprises a low stage compressor 144, a low stage heat output heat exchanger 148, a low stage throttle 152, and a low stage heat absorption heat exchanger 156. The low stage compressor 144 compresses a second refrigerant. The second refrigerant may be the same kind of refrigerant as the first refrigerant or maybe a different refrigerant. In this example, the second refrigerant has a normal boiling point between −10° C. and −100° C. Preferably the refrigerant is comprised of a hydrofluorocarbon (HFC) (for example, R-134a, R-32, or R-23), a fluorocarbon (FC) (for example R-218, R-116, or R-14), a hydrofluoroolefin (HFO) (for examples R-1234yf or R-1234ze), or a mixture of different molecules that include these types of compounds. Alternatively, hydrocarbons (HC's) (for example n-butane, iso-butane, propane, or ethane) may be used. However, preferably the resulting mixture is nonflammable and with a low global warming potential (GWP). Use of xenon or krypton, by itself or in a mixture is also a possibility to achieve temperatures below −100° C. The low stage compressor 144 compresses the second refrigerant to a pressure above 100 psi (689 kiloPa). The low stage heat output heat exchanger 148 passes heat from the second refrigerant to the first refrigerant. The heat exchange cools the second refrigerant. The second refrigerant condenses. The low stage throttle 152 provides a controlled expansion of the second refrigerant. The controlled expansion of the second refrigerant causes the second refrigerant to cool. The low stage throttle 152 helps to control the temperature of the expanded second refrigerant. The low stage heat absorption heat exchanger 156 absorbs heat. In this example, the low stage heat absorption heat exchanger 156 absorbs heat from an electrostatic chuck

(ESC) 160. A tool cooling system 164 or other heat transfer apparatus may be placed between the low stage heat absorption heat exchanger 156 and the ESC 160. In this embodiment, a coolant heat exchanger 168 is placed adjacent to the low stage heat absorption heat exchanger 156. A coolant is circulated between the coolant heat exchanger 168 and the ESC 160. The use of conventional liquid coolants below −40°

C. can be challenging due to very high viscosities that can develop at the very low temperatures described in this disclosure. In additional embodiments, very high pressure gas, at pressures of 400 psi, 1500 psi, 15,000 psi, or 150,000 psi are recirculated to regulate the temperature of the ESC 160 in place of liquid coolants, so as to deliver effective heat transfer and avoid the high viscosity issues associated with typical liquid coolants. Gases such as helium, neon, nitrogen, argon, krypton and xenon are example gases for this embodiment. In the example of a recirculated liquid coolant, or a very high pressure gas, a prime mover is required (not shown for clarity) to force the fluid in the loop shown in tool cooling system 164. Alternatively, other means of heat transfer are possible such as, but not limited to, a conductive element, a superconducting element, a heat pipe, or a less constrained version of a heat pipe known as a thermo-siphon where liquid fluid boils from the ESC 160, is condensed in low stage heat absorption heat exchanger 156 and fed by gravity or a liquid pump back to ESC 160.

The tool cooling system 164 comprises the low stage 124, the inlet 128 and the first throttle 132, the first heat transfer system 136, and the refrigerant return 140 of the high stage 120. Since the tool cooling system 164 does not include but uses the facility compressor 112 and the cooler 116, the volume and footprint of the tool cooling system 164 may be minimized As a result, the tool cooling system 164 is able to fit within an allotted space in the tool.

In an embodiment, the tool cooling system 164 is able to fit in a footprint of 584 mm×1435 mm with a height of no more than 2000 mm This embodiment is able to provide at least 11 kilowatts of cooling at a coolant at a temperature of −70° C. or colder to the ESC 160. In this embodiment, the ESC 160 is a substrate support. The embodiment is able to have a minimum coolant flow rate of at least 7 liters per minute. The embodiment is able to provide temperature control of the coolant with an accuracy of 1° C.

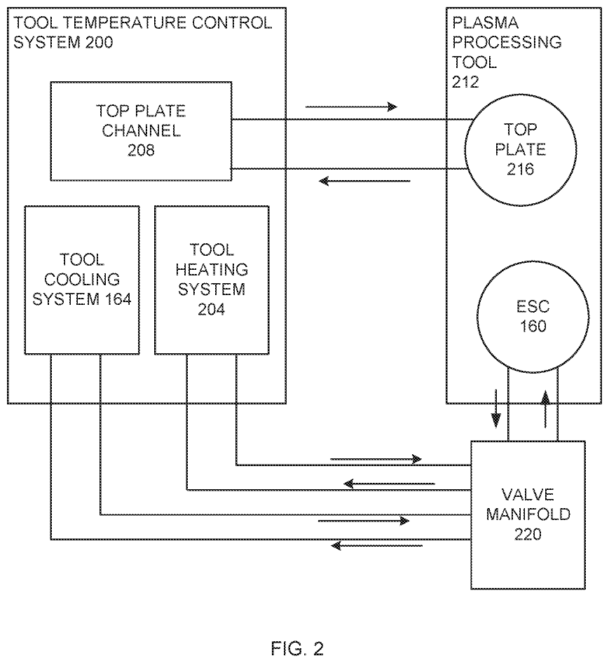

FIG. 2 is a schematic illustration of another embodiment. A tool temperature control system 200 may comprise the tool cooling system 164, a tool heating system 204, and a top plate channel 208. The tool temperature control system 200 is able to fit in an allotted footprint of 584 mm×1435 mm or an allotted footprint of 0.79 m² for a single chamber, or process module (PM). In an alternate embodiment, tool temperature control system 200 is able to fit in an allotted footprint of 584 mm×1435 mm or an allotted footprint of 0.79 m² with a height of no more than 2000 mm m² for a single chamber, or process module (PM). In some cases, chiller solutions for multiple PM's are combined. In these instances, the chiller footprint is increased based on the number of PM's serviced by the chiller. So, as an example, the chiller footprint of a chiller that serves two PM will be twice as large as a single PM solution (example: 1168 mm×1435 mm). In various embodiments, the footprint of the tool cooling system 164 is less than one of 110%, 90%, 80%, or 70% of the allotted footprint for the tool cooling system 164. In this embodiment, the tool cooling system 164 is able to provide at least 11 kilowatts of cooling at a coolant in a temperature range of −70° C. to 20° C. In another embodiment, the tool cooling system 164 is able to provide coolant in a temperature range of −90° C. to 40° C. to the ESC. The tool heating system 204 is able to provide at least 8 kilowatts of heating in the temperature range of −10° C. to 80° C. In another embodiment, the tool heating system 204 is able to provide coolant in a temperature range of −40° C. to 100° C. to the ESC 160. The top plate channel 208 is able to provide a temperature range of 10° C. to 55° C. The top plate channel 208 provides temperature control to a top plate 216. The tool cooling system 164 provides a cold loop to a valve manifold 220. The tool heating system 204 provides a hot loop to the valve manifold 220. The valve manifold 220 provides a temperature control loop to the ESC 160. The embodiment is able to have a coolant flow rate of at least 7 liters per minute. In an alternate embodiment, coolant flow rates of at least 17 liters per minute, 25 liters per minute or 35 liters per minute are provided such that the outlet coolant temperature is kept to a minimum. The embodiment is able to provide temperature control of the coolant with an accuracy of 1° C. In various embodiments, the temperature control system 200 may provide temperatures in the range of −80° C. to 40° C. In other embodiments, the temperature control system 200 provides temperatures in the range of −40° C. to 100° C. In other embodiments, the temperature control system 200 provides temperatures in the range of −90° C. to 100° C. In other embodiments, the temperature control range is −60° C. to 160° C., −70 ° C. to 160° C., −90 ° C. to 120° C., −90° C. to 140° C., or −100° C. to 160° C.

This embodiment provides a three-channel system. In a three-channel system, each channel has a specified temperature control range. In the three-channel system, shown in FIG. 2, the ESC 160 can be cooled by using a channel 1. Channel 1 circulates coolant that is in heat exchange with tool cooling system 164 and by using a channel 2. Channel 2 circulates coolant that is in a heat exchanger with tool heating system 204. In one embodiment, only one channel is circulating flow to the ESC 160 at a given time. The other channel is being recirculated without being directed to the ESC 160. Valve manifold 220 selects which of these coolant streams are delivered to the ESC 160.

In an alternate embodiment, valve manifold 220 is able to selectively mix coolant from channel 1 and channel 2 and deliver all, or a portion of these streams to ESC 160 and selectively bypass some or all of the channel 1 and channel 2 flow back to the tool cooling system 164 and the tool heating system 204. Additional variations are anticipated, including using a time offset to either precondition the ESC 160 in advance of an actual need, or changing the setpoints of tool cooling system 164 or the tool heating system 204 over time to protect the ESC 160 from excessive thermal stress, or to a achieve a desired process profile. In general, each channel may need a separate refrigeration solution. However, in some cases, depending on the required temperature for a particular temperature, the refrigeration capacity of the first or second refrigeration system may be shared among multiple channels. In some cases, if active refrigeration is not needed, and the heat removal can be accomplished by normal facility-provided cooling water, then a particular channel might be cooled using facility cooling water.

During select process steps, the valve manifold is switched to change which channel's flow is delivered to the ESC 160 and which is bypassed and returned to the chiller. In yet other embodiments the valve manifold 220 mixes select amounts of the first cold channel and the warmer second channel to regulate the ESC 160 temperature and in this arrangement, a portion of one or both channels bypasses the ESC 160 and is returned to the chiller. Those skilled in the art will recognize that these various embodiments can be used to regulate the ESC 160 temperature and to do so in a way to support various wafer processing steps. In some instances, the required rate of switching the ESC 160 temperature from one temperature to another is very rapid and may be as short as 5 minutes, 3 minutes, 1 minute or less. In some embodiments, the difference between these two temperatures is at least 60° C., or 80° C. or 100° C. In some instances, the amount of difference between one required temperature at the ESC 160 and the other is so great, that when coupled with a rapid change, damage to the ESC 160 may occur. In such cases, the rate of change is regulated by either altering the supply temperature of one or both channels over time in addition to the switching process.

Other embodiments include a process that is temperature sensitive such that a single step should be run much lower than −20° C., and a second step much greater than +20° C. Other embodiments include a temperature control loop using feedback based on backside ceramic temperature of the ESC 160. Other embodiments include the use of heat transfer fluids that are cooled or heated by the chiller and delivered to the ESC 160 that provide thermal conductivity and effective heat transfer to the ESC 160.

In another embodiment, the tool cooling system 164 may be a single compression cycle, using facility compressor 112 and the cooler 116. The first refrigerant preferably has a normal boiling point between +30° C. and −60° C. Preferably the refrigerant is comprised of a hydrofluorocarbon (HFC) (for example, R-245fa, R-236fa, R-134a, R-125, or R-32), a fluorocarbon (FC) (for example R-218) , a hydrofluoroolefin (HFO) (for example i.e. R-1234yf, -1233zd(E) -1234ze(E), -1234ze(Z), or HFO-1336mzz(Z)), or a mixture of different molecules that include these types of compounds. Alternatively, hydrocarbons (HC's) (for example n-butane, iso-butane, propane, or ethane) may be used but preferably the resulting mixture is nonflammable and with a low global warming potential (GWP). In another embodiment, the first refrigerant may be one or more of low global warming potential (GWP) refrigerants such as HFO's or low GWP HFC's, natural inorganic fluids (for example carbon dioxide, ammonia, argon, nitrogen, krypton, or xenon), xenon, by itself or in a mixture is also a possibility. In other embodiments, the first or second refrigerants may be a mixture of the above refrigerants. Such a mixture provides a mixed gas vapor compression system.

In various embodiments, the first throttle 132 controls the pressure so that the second pressure is above the triple point of the first refrigerant. In other embodiments, the tool cooling system 164 is able to provide at least 20 kilowatts of cooling. In other embodiments, the tool cooling system 164 uses an auto cascade system, such as an Edwards Vacuum, Polycold PFC-552 HC product, a Polycold MaxCool 2500L, a Polycold MaxCool 4000H, a thermoelectric system, or a mixed gas refrigeration system, such as an Edward's Vacuum Polycold PCC product.

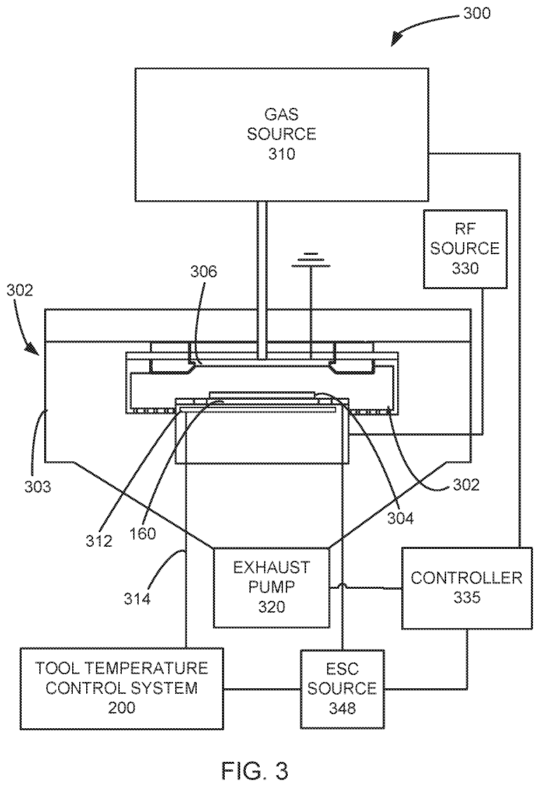

FIG. 3 is a schematic view of a processing tool 300 that may be used in an embodiment. In one or more embodiments, the processing tool 300 comprises a gas distribution plate 306 providing a gas inlet and the ESC 160, within a processing chamber 302, enclosed by a chamber wall 303. Within the processing chamber 302, a substrate 304 is positioned on top of the ESC 160, so that the ESC 160 is a substrate support. The ESC 160 may provide a bias from the ESC source 348. A gas source 310 is connected to the processing chamber 302 through the gas distribution plate 306. The tool temperature control system 200 is connected to the ESC 160, and provides temperature control of the ESC 160. There are one or more fluid connections 314, channels between the tool temperature control system 200 and the ESC 160. In some embodiments, the tool temperature control system 200 may include an additional heat exchange system directly connected to the ESC 160.

A radio frequency (RF) source 330 provides RF power to the ESC 160. In a preferred embodiment, 2 megahertz (MHz), 60 MHz, and optionally, 27 MHz power sources make up the RF source 330 and the ESC source 348. In this embodiment, one generator is provided for each frequency. In other embodiments, the generators may be in separate RF sources, or separate RF generators may be connected to different electrodes. For example, the upper electrode may have inner and outer electrodes connected to different RF sources. In this example, the gas distribution plate 306 is a grounded upper electrode or a top plate incorporated into the gas distribution plate 306. Other arrangements of RF sources and electrodes may be used in other embodiments. A controller 335 is controllably connected to the RF source 330, the ESC source 348, an exhaust pump 320, the tool temperature control system 200, and the gas source 310. An example of such an etch chamber is the Exelan Flex™ etch system manufactured by Lam Research Corporation of Fremont, Calif. A process module or plasma processing system may comprise the processing chamber 302, the gas source 310, the exhaust pump 320, the RF source 330, the ESC source 348, the controller 335, and other components of the processing tool 300. The process chamber can be a CCP (capacitively coupled plasma) reactor or an ICP (inductively coupled plasma) reactor.

In various embodiments, the tool temperature control system 200 is able to provide a coolant to the top plate in the temperature range of 10° C. to 80° C. In alternate embodiments, the coolant delivered to the top plate is in a temperature range of 10° C. to 80° C., 10° C. to 100° C., 10° C. to 120° C., 10° C. to 140° C., or 10° C. to 160° C. In various embodiments, the tool temperature control system 200 has a footprint that is less than or equal to the footprint of the processing chamber 302. In various embodiments, the tool temperature control system 200 has a footprint that is less than or equal to 25% of the footprint of the processing chamber 302.

In operation, a substrate 304 is mounted on the ESC 160. The tool temperature control system 200 would provide a refrigerant temperature of −90° C. to +100° C. at the ESC 160. Normally, a particular temperature is needed for a particular process step for the process occurring on the wafer. Different process steps may require different temperatures. Achieving these different temperatures is possible by either changing the refrigeration temperature set point to result in the desired coolant temperature. In some embodiments, the tool temperature control system 200 is as shown in FIG. 2. In these embodiments, the temperature setpoint of either the tool cooling system 164 and/or the tool heating system 204 are changed as needed. Alternatively, the ESC 160 temperature can be achieved by selectively mixing some or all of the coolant from tool cooling system 164 and tool heating system 204. The tool cooling system 164 is a first cooling apparatus. The tool heating system that can provide heating or cooling is a second cooling apparatus.

At the end of the wafer processing, there is an optional step to clean the wafer. This is called a waferless auto clean (WAC) process. For a WAC process, the valve manifold 220 is used to switch from cooling the wafer via the tool cooling system 164 to heating the wafer via the tool heating system 204. The typical construction of an ESC 160 includes multiple layers of components and elements, such as metal components, ceramic components, heaters, adhesive layers, various coatings, etc. The combination of these layers seeks to balance the needs for good heat transfer, good temperature uniformity, desired performance in the RF plasma environment, and the ability to resist erosion in the chemically aggressive process environment. The use of chillers to rapidly cool and heat the ESC can result in damage to the ESC, typically due to the failure of an interface between different internal elements and/or coatings. Therefore, a preferred embodiment is an ESC construction that can endure the change of temperatures from the low range to the high range and back again without failure or degradation of the ESC and the internal components, layers and coatings that the ESC is comprised of. In addition, when a temperature switch is made from a low-temperature coolant to a high-temperature coolant (or vice versa) it is important for the refrigeration systems to provide the required coolant temperature within 2 minutes to maximize utilization of the process module. For example, if channel 1 is normally operating at −70° C., and channel 2 is operating at +40° C. when the switch is made from cold operation at the ESC to hot operation at the ESC 160, the ESC set point of +40° C. must be achieved to +/−1° C. within 2 minutes. Likewise, when the switch is made from hot operation at the ESC 160 to cold operation at the ESC 160, the ESC set point of −70° C. must be achieved to +/−1° C. within 2 minutes. In alternate embodiments, the setpoint is reached to within +/−1° C. within 5 minutes, or within 3 minutes or within 1 minute.

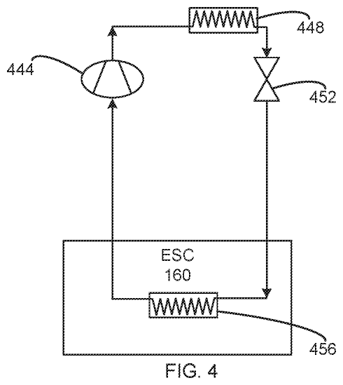

FIG. 4 is a schematic illustration of another embodiment providing direct ESC 160 cooling by a refrigerant. The embodiment comprises a compressor 444, a heat output heat exchanger 448, a throttle 452, and a direct ESC heat absorption heat exchanger 456. In this embodiment, the refrigerant passes into the ESC 160. In this embodiment, the refrigerant is CO₂. In another embodiment, the compressed CO₂ may be supplied from a fabrication facility. In another embodiment, the compressed CO₂ is supplied from a system that serves multiple plasma process systems. In yet another embodiment, an intermediate refrigerant circuit is used to precool the CO₂ after the cooler 116 or heat exchanger 448 and first throttle 132 or 452. This can be advantageous to lower the required compressor pressure to enable energy efficiency of the overall system. In other cases, this may be needed to enable standard CO₂ compression systems to achieve the desired cooling capacity when the cooling media for cooler 116 or heat exchanger 448 are higher than desired. In other embodiments, a liquid pump is used to increase the pressure of the liquefied CO₂ to further improve the cooling effect. An alternate embodiment includes a booster compressor to take the return refrigerant, at the refrigerant return 140 and raise the pressure to match that of the CO₂ compressions system of the fabrication facility 108. If multiple plasma process systems are utilizing this central compression system, such a localized intermediate compressor is expected to be beneficial in some circumstances.

In other embodiments, the wafer process applied is used to etch through multiple layers of devices on a wafer to support desired geometric attributes such as deep aspect ratios and or parallel via walls. In other embodiments, the wafer processes may be a dielectric etch including reactions that are both deposition and etch, a semiconductor process including a process that is temperature dependent, a dielectric film etch, or process for forming 3D memory devices. In other embodiments, the wafer process may deposit layers, such as in plasma-enhanced deposition.

While many of the above embodiments relate to use of a refrigeration loop to provide temperature control to a coolant that is delivered to the ESC, alternate embodiments use direct cooling or heating of the ESC using one or more of the above-mentioned refrigerants or refrigeration cycles. In these embodiments, switching from one temperature to another is accomplished by either a valve manifold 220 located close to the ESC or by having alternate control valves at the refrigeration unit to regulate the refrigerant temperature delivered to the ESC. In various embodiments, the cooling system may be at least one of a single stage vapor compression system, a cascade refrigeration system, an auto cascade system, a thermoelectric system, a mixed gas refrigerant system, or a Stirling refrigeration cycle, a Brayton refrigeration cycle, a Gifford McMahon refrigeration cycle or a pulse tube refrigeration cycle.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. An apparatus, comprising
a processing chamber;
a substrate support within the processing chamber, wherein the substrate support is for thermal contact with a substrate;
and
a cooling system for cooling the substrate support, wherein the cooling system comprises:
a first refrigeration system, comprising:
a first refrigerant inlet for receiving a first refrigerant from a first refrigerant source outside of the first refrigeration system, wherein the first refrigerant is at a first pressure;
a first throttle, wherein the first throttle allows a controlled expansion of the first refrigerant, wherein expansion of the first refrigerant cools the first refrigerant;
a first heat transfer system, for absorbing heat and transferring heat to the cooled first refrigerant; and
a first refrigerant return for directing the first refrigerant from the first refrigeration system at a second pressure away from the first refrigeration system.

2. The apparatus, as recited in claim 1, wherein the first refrigerant is carbon dioxide.

3. The apparatus, as recited in claim 2, wherein the first pressure is greater than 650 pounds per square inch (psi).

4. The apparatus, as recited in claim 3, wherein the second pressure is above a triple of CO₂ point and below 100 psi.

5. The apparatus, as recited in claim 2, wherein the first heat transfer system comprises at least one channel in the substrate support, wherein the first refrigerant flows through the at least one channel.

6. The apparatus, as recited in claim 1, further comprising a second refrigeration system using a second refrigerant, comprising:
a second refrigeration heat output heat exchanger;
a second refrigerant compressor for pressurizing the second refrigerant;
a second throttle, wherein the second throttle allows a controlled expansion of the second refrigerant, wherein expansion of the second refrigerant cools the second refrigerant; and
a second refrigeration heat absorption heat exchanger for absorbing heat from the substrate.

7. The apparatus, as recited in claim 6, wherein the second refrigeration system is a mixed gas refrigeration system.

8. The apparatus, as recited in claim 6, wherein the second refrigerant is at least one of carbon dioxide, a low global warming potential (GWP) refrigerant, and natural fluid.

9. An apparatus for processing a substrate, comprising
a plasma processing system, wherein the plasma processing system comprises a processing chamber;
a substrate support within the processing chamber; and
a cooling system that provides at least 20 kWatts of cooling, wherein the cooling system has a footprint with dimensions less than or equal to a footprint of the plasma processing system.

10. The apparatus, as recited in claim 9, wherein the cooling system is at least one of a single stage vapor compression system, a cascade refrigeration system, an auto cascade system, a thermoelectric system, a mixed gas refrigerant system, or a Stirling refrigeration cycle, a Brayton refrigeration cycle, a Gifford McMahon refrigeration cycle or a pulse tube refrigeration cycle.

11. The apparatus, as recited in claim 9, wherein the cooling system, comprises:
a first cooling apparatus; and
a second cooling apparatus.

12. The apparatus, as recited in claim 11, wherein the first cooling apparatus comprises a first cooling channel wherein the first cooling channel provides coolant of in the range of −90° C. to 40° C. to the substrate support and wherein the second cooling apparatus comprises a second cooling channel wherein the second cooling channel provides a coolant in the range of −40° C. to 100° C. to the substrate support.

13. The apparatus, as recited in claim 12, further comprising a top plate, and wherein the cooling system further comprises a top plate cooling apparatus comprising a top plate channel, wherein the top plate channel provides coolant to the top plate, wherein the coolant is provided in the temperature range of 10° C. to 100° C.

14. The apparatus, as recited in claim 9, wherein the footprint of the cooling system is less than 25% of the footprint of the plasma processing system.

15. The apparatus, as recited in claim 9, wherein the footprint of the cooling system is less than one of 584 mm by 1435 mm, or 0.79 m² per plasma processing system.

16. The apparatus, as recited in claim 15, wherein the footprint of the cooling system has a height no greater than 2000 mm

17. An apparatus for processing a substrate, comprising
a processing chamber;
a substrate support within the processing chamber, wherein the substrate support comprises various components, layers and coatings; and
a temperature control system, comprising:
a tool cooling system;
a tool heating system; and
a plurality of channels, wherein the temperature control system is for cooling the substrate support such that no damage or degradation occurs to the substrate support due to temperature changes that occur when switching from one temperature set point to another, especially when rapidly switching the temperature control system from one channel to another channel of the plurality of channels.

18. The apparatus, as recited in claim 17, wherein the temperature control system is configured to provide cooling in a first temperature range of −70° C. to +40° C. and a second temperature range of −40° C. to +100° C.

19. The apparatus, as recited in claim 17, wherein the tool cooling system comprises a chiller that is able to recover within two minutes after switching from the tool cooling system to the tool heating system, such that a temperature of a coolant for a channel being provided to the substrate support is within 1° C.

20. The apparatus, as recited in claim 17, wherein the temperature control system is configured to provide cooling in a first temperature range of −180° C. to +40° C. and a second temperature range of −40° C. to +100° C. and wherein the temperature control system delivers a very high pressure gas to channels of the substrate support to provide heat transfer to the substrate.

21. An apparatus for processing a substrate, comprising
a processing chamber;
a substrate support within the processing chamber; and
a cooling system for cooling the substrate support, wherein the cooling system comprises:
a first refrigeration system with a first refrigerant comprising CO₂, the first refrigeration system comprising:
a first compressor for compressing the first refrigerant to first pressure;
a first heat transfer device for transferring heat from the compressed first refrigerant;
a first throttle, wherein the first throttle allows a controlled expansion of the first refrigerant, wherein the controlled expansion of the first refrigerant cools the first refrigerant; and
at least one channel in the substrate support, wherein the first refrigerant flows through the at least one channel.

22. The apparatus, as recited in claim 21, wherein the first pressure is greater than 650 pounds per square inch (psi).
